(19) United States
(12) Patent Application Publication
(10) Pub. No.: US 2025/0171612 A1
(43) Pub. Date: May 29, 2025

(54) FILM, PREPARATION METHOD THEREOF AND PHOTOELECTRIC DEVICE

(71) Applicants: Guangdong Juhua Research Institute of Advanced Display, Guangzhou (CN); TCL Technology Group Corporation, Huizhou (CN)

(72) Inventor: Xiongfeng LIN, Guangzhou (CN)

(73) Assignees: Guangdong Juhua Research Institute of Advanced Display, Guangzhou (CN); TCL Technology Group Corporation, Huizhou (CN)

(21) Appl. No.: 18/957,752

(22) Filed: Nov. 23, 2024

(30) Foreign Application Priority Data
Nov. 23, 2023 (CN) 202311577639.1

(51) Int. Cl. C08K 3/11; C08J 5/18; C09K 11/08; H10K 50/115; H10K 71/12; H10K 77/10; H10K 85/40; H10K 102/00

(52) U.S. Cl. CPC C08K 3/11; C08J 5/18; C09K 11/08; H10K 50/115; H10K 71/12; H10K 77/111; H10K 85/40; C08J 2301/02; C08K 2201/011; H10K 2102/311; H10K 2102/321

(57) ABSTRACT

The present disclosure film, preparation method thereof and photoelectric device. The film includes a nanocellulose and an inorganic nanoparticle, wherein the nanocellulose has a porous skeleton, and the inorganic nanoparticle is located in pores of the porous skeleton. By doping the nanocellulose with toughness into the inorganic nanoparticle, the inorganic nanoparticle can be embedded into the skeleton of the nanocellulose to limit the movement of the inorganic nanoparticle, so that the displacement of the inorganic nanoparticle during the bending process of the film can be reduced. And the situation that the film is cracked or broken during the bending process can be slowed down or eliminated, thereby improving the bending resistance of the film. When the film is applied to a flexible photoelectric device, the service life of the flexible photoelectric device can be prolonged because the film has good bending resistance.

This application claims priority to Chinese Application No. 202311577639.1, entitled “FILM AND PREPARATION METHOD THEREOF, PHOTOELECTRIC DEVICE AND PREPARATION METHOD THEREOF, AND DISPLAY DEVICE”, filed on Nov. 23, 2023. The entire disclosures of the above application are incorporated herein by reference.

### TECHNICAL FIELD

The present disclosure relates to a field of photoelectric device technologies, and more particularly, to film, preparation method thereof and photoelectric device.

### BACKGROUND

Electroluminescent devices include OLED (Organic Light-Emitting Diode) and QLED (Quantum Dot Light-Emitting Diode). QLED has the advantages of high colour saturation, wet preparation and high stability, which makes the research of QLED attract more and more attention. OLED has been widely used in display, lighting, smart wear and other fields because of its good self-luminous characteristics, high contrast, fast response and flexible display.

The functional layer in an electroluminescent device can be a film composed of a plurality of inorganic nanoparticle (such as quantum dot particle). However, the bending resistance of such a film is poor. When the inorganic nanoparticle in the film are bent under the action of external force, cracks or even fractures often occur in the film, which will lead to changes in the carrier transmission of the electroluminescent device, and then lead to the decline of the performance of the electroluminescent device.

### Technical Solution

In view of this, the present disclosure provides a film, a preparation method thereof and a photoelectric device.

According to a first aspect, the present disclosure provides a film. The film includes a nanocellulose and an inorganic nanoparticle. The nanocellulose has a porous skeleton, and the inorganic nanoparticle is located in pores of the porous skeleton.

In some embodiments, a mass ratio of the nanocellulose to the inorganic nanoparticle is (0.01-0.05): 1. The nanocellulose is selected from one or more of cellulose nanocrystal, cellulose nanofiber, and bacterial nanocellulose.

In some embodiments, the film further comprising a crosslinking agent selected from one or more of silane and acid anhydride.

In some embodiments, the silane is connected to the nanocellulose. The acid anhydride is connected to the nanocellulose. A mass ratio of the crosslinking agent to the nanocellulose is (0.5-10): 100.

In some embodiments, the silane is connected to the nanocellulose through at least one siloxane bond. The acid anhydride is connected to the nanocellulose through at least one ester bond.

In some embodiments, the silane is selected from one or more of 3-aminopropyl triethoxysilane, methyltrioxysilane, styrene dimethoxysilane, and aminopropyl trimethoxysilane. The acid anhydride is selected from one or more of maleic anhydride, succinic anhydride, and phthalic anhydride.

In some embodiments, the crosslinking agent is the silane, a mass ratio of the crosslinking agent to the nanocellulose is (0.5-5): 100; or the crosslinking agent is the acid anhydride, a mass ratio of the crosslinking agent to the nanocellulose is (1-10): 100; or the crosslinking agent comprises a mixture of the silane and the acid anhydride, and a mass ratio of the silane to the acid anhydride is (1-100):(1-100).

In some embodiments, a material of the inorganic nanoparticle is selected from quantum dot luminescent material. The quantum dot luminescent material is selected from one or more of single structure quantum dot and core-shell structure quantum dot; a material of the single structure quantum dot, a core material of the core-shell quantum dot and a shell material of the core-shell quantum dot is independently selected from one or more of II-VI compound, IV-VI compound, III-V compound and I-III-VI compound. The core-shell structure quantum dot includes one or more shell layers; the II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAlNSb, GaAlPAs, GaAlPSb, GalInNP, GaInNAs, GaInNSb, GalnPAs, GaInPSb, InAINP, InAINAs, InAINSb, InAlPAs, and InAlPSb. The I-III-VI compound is selected from one or more of CuInS₂, CuInSe₂, and AgInS₂.

A second aspect, the present disclosure provides a preparation method of a film. The preparation method includes: providing an inorganic nanomaterial solution, wherein the inorganic nanomaterial solution comprises a nanocellulose, an inorganic nanoparticle and a solvent; and depositing the inorganic nanomaterial solution to obtain a film, wherein the film comprises the nanocellulose and the inorganic nanoparticle, the nanocellulose forms a porous skeleton, and the inorganic nanoparticle is located in pores of the porous skeleton.

In some embodiments, in the inorganic nanomaterial solution, a concentration of the inorganic nanoparticle ranges between 10 mg/ml-50 mg/ml. A concentration of the nanocellulose ranges between 0.1 mg/ml-2.5 mg/ml. A mass ratio of the nanocellulose to the inorganic nanoparticle is (0.01-0.05): 1.

In some embodiments, the inorganic nanomaterial solution further comprises a crosslinking agent selected from one or more of silane and acid anhydride.

In some embodiments, a mass ratio of the crosslinking agent to the nanocellulose is (0.5-10): 100. A concentration of the crosslinking agent in the inorganic nanomaterial solution ranges between 0.0005 mg/ml-0.25 mg/ml.

In some embodiments, the crosslinking agent is the silane, a mass ratio of the crosslinking agent to the nanocellulose is (0.5-5): 100, and a concentration of the crosslinking agent in the inorganic nanomaterial solution ranges between 0.0005 mg/ml-0.125 mg/ml.

In some embodiments, the crosslinking agent is the acid anhydride, a mass ratio of the crosslinking agent to the nanocellulose is (1-10): 100, and a concentration of the crosslinking agent in the inorganic nanomaterial solution ranges between 0.001 mg/ml-0.25 mg/ml.

In some embodiments, the depositing the inorganic nanomaterial solution to obtain the film comprises: depositing the inorganic nanomaterial solution to obtain a film layer to be crosslinked; and heat-treating the film layer to be crosslinked in an environment with a temperature of 80° C.-100° C. and a humidity of 80%-100% for 10 min-60 min, so that the crosslinking agent and the nanocellulose have a crosslinking reaction to obtain the film.

In some embodiments, the nanocellulose is selected from one or more of cellulose nanocrystal, cellulose nanofiber, and bacterial nanocellulose. A material of the inorganic nanoparticle is selected from quantum dot luminescent material. The quantum dot luminescent material is selected from one or more of single structure quantum dot and core-shell structure quantum dot. A material of the single structure quantum dot, a core material of the core-shell quantum dot and a shell material of the core-shell quantum dot is independently selected from one or more of II-VI compound, IV-VI compound, III-V compound and I-III-VI compound; the core-shell structure quantum dot includes one or more shell layers; the II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GaInNP, GalnNAs, GalnNSb, GalnPAs, GalnPSb, InAINP, InAINAs, InAINSb, InAlPAs, and InAlPSb; the I-III-VI compound is selected from one or more of CuInS₂, CuInSe₂, and AgInS₂.

A third aspect, the present disclosure provides a photoelectric device which includes a first electrode, a second electrode and a film therebetween, and the film comprising a nanocellulose and an inorganic nanoparticle, wherein the nanocellulose has a porous skeleton, and the inorganic nanoparticle is located in pores of the porous skeleton.

In some embodiments, the photoelectric device further comprising: a hole injection layer, located on the first electrode; a hole transport layer, located between the film and the first electrode; and an electron transport layer located between the film and the second electrode, wherein the first electrode is an anode and the second electrode is a cathode.

In some embodiments, the photoelectric device further comprising: an electron transport layer, located between the film and the first electrode; a hole transport layer, located between the film and the second electrode; and a hole injection layer located between the hole transport layer and the second electrode, wherein the first electrode is a cathode and the second electrode is an anode.

In some embodiments, a material of the hole transport layer is selected from one or more of 4,4′-N,N′-dicarbcarbazolyl-biphenyl, poly [bis(4-phenyl) (2,4,6-trimethylphenyl)amine], N,N′-diphenyl-N,N′-bis(1-naphthyl)-1,1′-biphenyl-4,4″-diamine, N,N′-diphenyl-N,N′-bis(1-naphthyl)-4,4′-diamine, poly(N,N′ bis(4-butylphenyl)-N,N′-bis(phenyl)benzidine), N,N′-bis(4-(N,N′-diphenyl-amino)phenyl)-N,N′-diphenyl benzidine, 4,4′,4′-tris(N-carbazolyl)-triphenylamine, 4,4′,4′-tris(N-3-methylphenyl-N-phenylamino)triphenylamine, poly [(9,9′-dioctyl fluorene-2,7-diyl)-co-(4,4′-(N-(4-sec-butylphenyl)diphenylamine))], poly(N-vinylcarbazole) and its derivatives, N,N′-bis(1-naphthyl)-N,N′-diphenyl-1,1′-biphenyl-4-4′-diamine, poly(phenylene vinylene), poly [2-methoxy-5-(2-ethylhexyloxy)-1,4-phenylene vinylene], poly [2-methoxy-5-(3′,7′-dimethyloctyloxy)-1,4-phenylene vinylene], 2,2′,7,7′-tetrakis [N,N-bis(4-methoxyphenyl)amino]-9,9′-spiro-fluorene, 4,4′-cyclohexyl bis [N,N-bis(4-methylphenyl) aniline], 1,3-bis(carbazole-9-yl)benzene, polyaniline, polypyrrole, poly(p)phenylene vinylene, aromatic tertiary amine, polynuclear aromatic tertiary amine, 4,4′-bis(p-carbazolyl)-1,1′-biphenyl compound, N,N,N′,N′-tetraarylbenzidine, poly(3,4-ethylenedioxythiophene)-polystyrene sulfonic acid and its derivatives, polymethacrylate and its derivatives, poly(9,9-octylfluorene) and its derivatives, polyspirofluorene and its derivatives, and polythiophene and its derivatives. A material of the hole injection layer is selected from one or more of poly(3,4-ethylenedioxythiophene)-polystyrene sulfonic acid, copper phthalocyanine, 2,3,6,7,10,11-hexacyano-1,4,5,8,9,12-hexazaphenanthrene, polyoxyethyl cephene, PEDOT: PSS doped with MoO₃, 4,4′,4′-tris(N-3-methylphenyl-N-phenylamino)triphenylamine, tetracyanoquinone dimethane, transition metal oxide, and transition metal chalcogenide; and the transition metal oxide is selected from one or more of MoOₓ, VOₓ, WOₓ, CrOₓ and CuO, the metal chalcogenide is selected from one or more of MoS₂, MoSe₂, WS₂, WSe₂, and CuS. Amaterial of the electron transport layer is selected from one or more of metal oxide, doped metal oxide, II-VI semiconductor material, III-V semiconductor material and I—III-VI semiconductor material, and the metal oxide is selected from one or more of ZnO, BaO, TiO₂, and SnO₂; a metal oxide in the doped metal oxide is selected from one or more of ZnO, TiO₂, and SnO₂, a doping element is selected from one or more of Al, Mg, Li, In and Ga; and the II-VI semiconductor family material is selected from one or more of ZnS, ZnSe and CdS; the III-V semiconductor material is selected from one or more of InP and GaP; the I-III-VI semiconductor material is selected from one or more of CuInS and CuGaS. The first electrode and the second electrode each is independently selected from a doped metal oxide electrode, a composite electrode, a graphene electrode, a carbon nanotube electrode, a simple metal electrode, or an alloy electrode; and a material of the doped metal oxide electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, aluminum-doped magnesium oxide, and cadmium-doped zinc oxide; and the composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, Ca/Al, LiF/Ca, LiF/Al, BaF₂/Al, CsF/Al, CaCO₃/Al, and BaF₂/Ca/Al. A material of the metallic electrode is selected from Ag, Mg, Al, Au, Ga, Ni, Pt, Ir, Cu, Mo, Ca, and Ba.

According to the film provided by this present disclosure, by doping the nanocellulose with toughness into the inorganic nanoparticle, the inorganic nanoparticle can be embedded into the skeleton of the nanocellulose to limit the movement of the inorganic nanoparticle, so that the displacement of the inorganic nanoparticle during the bending process of the film can be reduced. And the situation that the film is cracked or broken during the bending process can be slowed down or eliminated, thereby improving the bending resistance of the film. When the film is applied to a flexible photoelectric device, the service life of the flexible photoelectric device can be prolonged because the film has good bending resistance.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a flowchart of a method for preparing a film according to an embodiment of the present disclosure.

FIG. 2 is a schematic diagram of the first structure of a photoelectric device according to another embodiment of the present disclosure.

FIG. 3 is a schematic diagram of the second structure of a photoelectric device according to another embodiment of the present disclosure.

FIG. 4 is a flowchart of a method for preparing a photoelectric device according to another embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The embodiments of the present disclosure provide a quantum dot light emitting diode device, a manufacturing method thereof and a display panel. Detailed descriptions are given below. It should be noted that the order in which the following embodiments are described is not intended to limit the preferred order of the embodiments.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

The present disclosure discloses a film, including: a nanocellulose and an inorganic nanoparticle, wherein the nanocellulose has a porous skeleton, and the inorganic nanoparticle is located in pores of the porous skeleton.

Illustratively, a mass ratio of the nanocellulose to the inorganic nanoparticle is (0.01-0.05): 1, such as 0.01:1, 0.02:1, 0.03:1, 0.04:1, and 0.05:1, etc.

Illustratively, a material of the inorganic nanoparticle is selected from quantum dot luminescent material.

Illustratively, the quantum dot luminescent material is selected from one or more of single structure quantum dot and core-shell structure quantum dot. Specifically, a material of the single structure quantum dot, a core material of the core-shell quantum dot and a shell material of the core-shell quantum dot is independently selected from one or more of II-VI compound, IV-VI compound, III-V compound and I-III-VI compound. The core-shell structure quantum dot includes one or more shell layers. The II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAS, AlPSb, InNP, InNAs, InNSb, InPAs, InPSb, GaAINP, GaAINAs, GaAINSb, GaAlPAs, GaAlPSb, GalnNP, GalnNAs, GaInNSb, GalnPAs, GalnPSb, InAINP, InAINAs, InAINSb, InAlPAs, and InAlPSb. The I-III-VI compound is selected from one or more of CuInS₂, CuInSe₂, and AgInS₂.

In some embodiments, the inorganic nanoparticle is quantum dot particle.

In the present disclosure, when a mass ratio of nanocellulose to inorganic nanoparticle is (0.01-0.05):1, not only the toughness of the film can be enhanced, but also the conductivity of the film will not be affected, improving electrical properties and extending service life of the photoelectric device. It should be noted that when a mass ratio of the nanocellulose to the inorganic nanoparticle is greater than or equal to 0.01:1, the nanocellulose can well maintain the stability of the position of the quantum dot particle when the film is bent, thereby slowing down or eliminating the occurrence of cracks or fractures in the film during bending, and further improving the stability and service life of photoelectric device. When a mass ratio of the nanocellulose to the inorganic nanoparticle is less than or equal to 0.05:1, due to the low content of nanocellulose, the nanocellulose has little influence on the conductivity of the film, and thus on the luminous efficiency of the photoelectric device.

Illustratively, the nanocellulose is selected from one or more of cellulose nanocrystal, cellulose nanofiber, and bacterial nanocellulose.

Illustratively, the film further includes a crosslinking agent, which is selected from one or more of silane and acid anhydride. A mass ratio of the crosslinking agent to the nanocellulose is (0.5-10): 100, such as 0.5:100, 1:100, 2:100, 3:100, 4:100 and 5:100, etc.

It should be noted that due to the poor thermal stability of the nanocellulose, the damage of nanocellulose may occur in high temperature use environment or storage environment. Therefore, by adding the crosslinking agent into the film, different nanocellulose molecules or different segments in the same nanocellulose molecule can be crosslinked, thereby improving the thermal stability of nanocellulose and further improving the thermal stability of the film.

Illustratively, when the crosslinking agent is silane, the silane is connected to the nanocellulose. Illustratively, the silane is connected to the nanocellulose through at least one siloxane bond.

It should be noted that silane can react with hydroxyl groups of nanocellulose to produce siloxane. Because the same silane molecule can react with different nanocellulose molecules or with different segments in the same nanocellulose molecule, the effect of crosslinking nanocellulose can be achieved.

Illustratively, when the crosslinking agent is the silane, a mass ratio of the crosslinking agent to the nanocellulose is (0.5-5): 100, such as 0.5:100, 1:100, 2:100, 3:100, 4:100, and 5:100, etc. The silane is selected from one or more of 3-aminopropyl triethoxysilane, methyltrioxysilane, styrene dimethoxysilane, and aminopropyl trimethoxysilane.

Illustratively, when the crosslinking agent is an acid anhydride, the acid anhydride is connected to the nanocellulose. Illustratively, the acid anhydride is connected to the nanocellulose through at least one ester bond.

It should be noted that when the crosslinking agent is acid anhydride, the acid anhydride can react with the hydroxyl group of nanocellulose to generate ester. Because the same acid anhydride molecule can react with different nanocellulose molecules or different segments in the same nanocellulose molecule, the effect of crosslinking nanocellulose can be achieved.

Illustratively, when the crosslinking agent is the acid anhydride, a mass ratio of the crosslinking agent to the nanocellulose is (1-10): 100, such as 1:100, 2:100, 3:100, 4:100, 5:100, 6:100, 7:100, and 8:100, etc. The acid anhydride is selected from one or more of maleic anhydride, succinic anhydride, and phthalic anhydride.

Illustratively, the crosslinking agent includes a mixture of the silane and the acid anhydride, and a mass ratio of the silane to the acid anhydride is (1-100):(1-100), such as 1:1, 1:10, 1:20, 1:30, 1:40, 1:50, 1:60, 1:70, 1:80, 1:90, 1:100, 100:1, 90:1 and 80:1, 10:1, etc. At this moment, a mass ratio of the crosslinking agent to the nanocellulose is (0.5-10): 100, such as 0.5:100, 1:100, 2:100, 3:100, 4:100, 5:100, 6:100, and 7:100, etc.

Illustratively, a thickness of the film ranges from 10 nm to 50 nm, such as 10 nm, 12 nm, 15 nm, 18 nm, 20 nm, 22 nm, 25 nm, 28 nm, 30 nm, 32 nm, 35 nm, 38 nm, 40 nm, 42 nm, 45 nm, 48 nm, and 50 nm, etc.

According to the film provided by this present disclosure, the inorganic nanoparticle can be embedded into the skeleton of the nanocellulose by doping the nanocellulose with toughness into the inorganic nanoparticle. Because the skeleton of nanocellulose can limit the movement of inorganic nanoparticle, it can reduce the displacement of inorganic nanoparticle in the bending process of the film, and then it can slow down or eliminate the crack or fracture of the film during the bending process, thus improving the bending resistance of the film. By limiting the mass ratio of nanocellulose to inorganic nanoparticle to (0.01-0.05): 1, the toughness of the film can be enhanced without affecting the conductivity of the film, so that the photoelectric device can have better electrical properties and longer service life at the same time. When the film is applied to a flexible photoelectric device, the service life of the flexible photoelectric device can be prolonged because the film has good bending resistance.

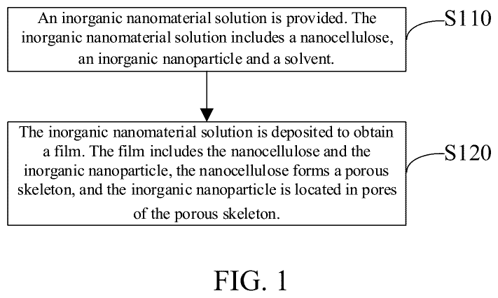

Referring to FIG. 1, the present disclosure proposes a preparation method of a film which includes steps S110 and S120.

In step S110, an inorganic nanomaterial solution is provided. The inorganic nanomaterial solution includes a nanocellulose, an inorganic nanoparticle and a solvent.

In step S120, the inorganic nanomaterial solution is deposited to obtain a film. The film includes the nanocellulose and the inorganic nanoparticle, the nanocellulose forms a porous skeleton, and the inorganic nanoparticle is located in pores of the porous skeleton.

Illustratively, a mass ratio of the nanocellulose to the inorganic nanoparticle is (0.01-0.05):1.

Illustratively, the solvent is selected from one or more of octane, n-hexane, heptane, toluene, chloroform, and dichloromethane.

Illustratively, in the inorganic nanomaterial solution, a concentration of the inorganic nanoparticle ranges between 10 mg/ml to 50 mg/ml, such as 10 mg/ml, 20 mg/ml, 30 mg/ml, 40 mg/ml, and 50 mg/ml, etc. A concentration of the nanocellulose ranges between 0.1 mg/ml to 2.5 mg/ml, such as 0.1 mg/ml, 0.5 mg/ml, 0.8 mg/ml, 1.0 mg/ml, 1.2 mg/ml, 1.5 mg/ml, 1.8 mg/ml, 2.0 mg/ml, and 2.2 mg/ml, etc.

Illustratively, the inorganic nanomaterial solution further includes a crosslinking agent which is selected from one or more of silane and acid anhydride, and a mass ratio of the crosslinking agent to the nanocellulose is (0.5-10): 100, such as 0.5:100, 1:100, 2:100, 3:100, 4:100, and 5:100, etc.

Illustratively, a concentration of the crosslinking agent in the inorganic nanomaterial solution ranges between 0.0005 mg/ml to 0.25 mg/ml, such as 0.0005 mg/ml, 0.001 mg/ml, 0.005 mg/ml, 0.05 mg/ml, and 0.125 mg/ml, etc.

Illustratively, when the crosslinking agent is the silane, a mass ratio of the crosslinking agent to the nanocellulose is (0.5-5): 100, and a concentration of the crosslinking agent in the inorganic nanomaterial solution ranges between 0.0005 mg/ml to 0.125 mg/ml, such as 0.0005 mg/ml, 0.001 mg/ml, and 0.005 mg/ml, etc.

When the crosslinking agent is the acid anhydride, a mass ratio of the crosslinking agent to the nanocellulose is (1-10): 100, and a concentration of the crosslinking agent in the inorganic nanomaterial solution ranges between 0.001 mg/ml to 0.25 mg/ml, such as 0.001 mg/ml, 0.005 mg/ml, 0.01 mg/ml, and 0.05 mg/ml, etc.

Illustratively, the inorganic nanomaterial solution further includes the crosslinking agent. The step of depositing the inorganic nanomaterial solution to obtain the film includes: depositing the inorganic nanomaterial solution to obtain a film layer to be crosslinked, and heat-treating the film layer to be crosslinked in an environment with a temperature of 80° C.-100° C. (such as, 80° C., 85° C., 90° C., 95° C., and 100° C., etc.) and a humidity of 80%-100% (such as, 80%, 85%, 90%, 95%, and 100%, etc.) for 10 min-60 min (such as, 10 min, 20 min, 30 min, 40 min, 50 min, and 60 min, etc.), so that the crosslinking agent and the nanocellulose have a crosslinking reaction to obtain the film.

It should be noted that the porous skeleton of the nanocellulose in the film is formed in the process of film formation.

Illustratively, the inorganic nanomaterial solution can be deposited by a spin coating method. It should be noted that when the spin coating method is used to deposit the inorganic nanomaterial solution, part of the solvent in the inorganic nanomaterial solution will be thrown off due to centrifugation during the spin coating process, and at the same time, it will be accompanied by natural volatilization during the spin coating process, so the film obtained after the spin coating is almost dry, and no additional drying treatment is needed.

It can be understood that when other methods (such as inkjet printing) are used to deposit the inorganic nanomaterial solution, a wet film layer formed by the inorganic nanomaterial solution can also be dried (such as heating or natural evaporation) to obtain a dried film.

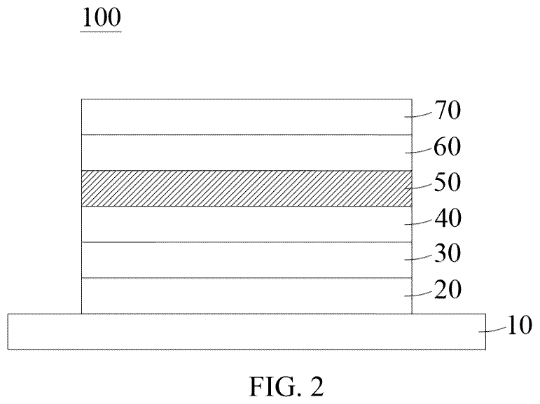

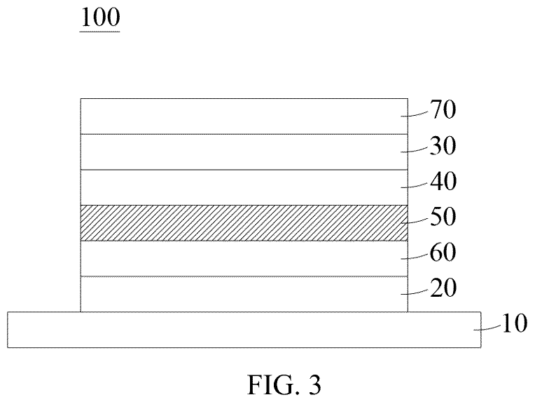

Referring to FIG. 2 and FIG. 3, the present disclosure a photoelectric device 100, including:
a first electrode 20 and a second electrode 70 which are oppositely arranged, and
a film 50 arranged between the first electrode 20 and the second electrode 70.

The film 50 can be a film in any of the above embodiments or a film prepared by a preparation method in any of the above embodiments.

Referring to FIG. 2 and FIG. 3, the photoelectric device 100 further includes a substrate 10, which is disposed on a side of the first electrode 20 facing away from the film 50.

Illustratively, the substrate 10 may be a flexible substrate or a rigid substrate. Illustratively, a material of the flexible substrate 10 may be an organic polymer, such as polyethylene terephthalate (PET) or polyimide (PI). Illustratively, the rigid substrate 10 may be a glass substrate.

It can be understood that when the substrate 10 is a flexible substrate 10, the photoelectric device 100 is a flexible photoelectric device 100.

Referring to FIG. 2, when the first electrode 20 is an anode and the second electrode 70 is a cathode, the photoelectric device 100 further includes a hole injection layer 30 and a hole transport layer 40 located between the film 50 and the first electrode 20, and an electron transport layer 60 located between the film 50 and the second electrode 70, wherein the hole injection layer 30 is located near the first electrode 20 and the hole transport layer 40 is located near the film 50.

Referring to FIG. 3, when the first electrode 20 is a cathode and the second electrode 70 is a anode, the photoelectric device 100 further includes an electron transport layer 60 between the film 50 and the first electrode 20, and a hole injection layer 30 and a hole transport layer 40 between the film 50 and the second electrode 70, wherein the hole injection layer 30 is arranged near the second electrode 70, and the hole transport layer 40 is arranged near the film 50.

Illustratively, a material of the hole transport layer 40 is selected from one or more of 4,4′-N,N′-dicarbcarbazolyl-biphenyl (CBP), poly [bis(4-phenyl) (2,4,6-trimethylphenyl)amine](PTAA), N,N′-diphenyl-N,N′-bis(1-naphthyl)-1,1′-biphenyl-4,4″-diamine (a-NPD), N,N′-diphenyl-N,N′-bis(1-naphthyl)-4,4′-diamine (TPD), poly(N,N′ bis(4-butylphenyl)-N,N′-bis(phenyl)benzidine) (Poly-TPD), N,N′-bis(4-(N,N′-diphenyl-amino)phenyl)-N,N′-diphenyl benzidine (DNTPD), 4,4′,4′-tris(N-carbazolyl)-triphenylamine (TCTA), 4,4′,4′-tris(N-3-methylphenyl-N-phenylamino)triphenylamine (m-MTDATA), poly [(9,9′-dioctyl fluorene-2,7-diyl)-co-(4,4′-(N-(4-sec-butylphenyl)diphenylamine))](TFB), poly(N-vinylcarbazole) (PVK) and its derivatives, N,N′-bis(1-naphthyl)-N,N′-diphenyl-1,1′-biphenyl-4-4′-diamine (NPB), poly(phenylene vinylene) (PPV), poly [2-methoxy-5-(2-ethylhexyloxy)-1,4-phenylene vinylene](MEH-PPV), poly [2-methoxy-5-(3′,7′-dimethyloctyloxy)-1,4-phenylene vinylene](MOMO-PPV), 2,2′,7,7′-tetrakis [N,N-bis(4-methoxyphenyl)amino]-9,9′-spiro-fluorene (spiro-omeTAD), 4,4′-cyclohexyl bis [N,N-bis(4-methylphenyl) aniline](TAPC), 1,3-bis(carbazole-9-yl)benzene (MCP), polyaniline, polypyrrole, poly(p) phenylene vinylene, aromatic tertiary amine, polynuclear aromatic tertiary amine, 4,4′-bis(p-carbazolyl)-1,1′-biphenyl compound, N,N,N′,N′-tetraarylbenzidine, poly(3,4-ethylenedioxythiophene)-polystyrene sulfonic acid (PEDOT: PSS) and its derivatives, polymethacrylate and its derivatives, poly(9,9-octylfluorene) and its derivatives, polyspirofluorene and its derivatives, and polythiophene (TPH) and its derivatives.

Illustratively, a material of the hole injection layer 30 is selected from one or more of poly(3,4-ethylenedioxythiophene)-polystyrene sulfonic acid (PEDOT: PSS), copper phthalocyanine (CuPc), 2,3,6,7,10,11-hexacyano-1,4,5,8,9,12-hexazaphenanthrene (HAT-CN), polyoxyethyl cephene (PEDOT), PEDOT: PSS doped with MoO₃ (PEDOT: PSS-MoO₃), 4,4′,4′-tris(N-3-methylphenyl-N-phenylamino)triphenylamine (m-MTDATA), tetracyanoquinone dimethane (F4-TCNQ), transition metal oxide, and transition metal chalcogenide. Illustratively, the transition metal oxide is selected from one or more of MoOₓ, VOₓ, WOₓ, CrOₓ and CuO. Illustratively, the metal chalcogenide is selected from one or more of MoS₂, MoSe₂, WS₂, WSe₂, and CuS.

Illustratively, a material of the electron transport layer 60 is selected from one or more of metal oxide, doped metal oxide, II-VI semiconductor material, III-V semiconductor material and I-III-VI semiconductor material, and the metal oxide is selected from one or more of ZnO, BaO, TiO₂, and SnO₂; a metal oxide in the doped metal oxide is selected from one or more of ZnO, TiO₂, and SnO₂, a doping element is selected from one or more of Al, Mg, Li, In and Ga; and the II-VI semiconductor family material is selected from one or more of ZnS, ZnSe and CdS; the III-V semiconductor material is selected from one or more of InP and GaP; the I-III-VI semiconductor material is selected from one or more of CuInS and CuGaS.

Illustratively, the first electrode 20 and the second electrode 70 each is independently selected from a doped metal oxide electrode, a composite electrode, a graphene electrode, a carbon nanotube electrode, a simple metal electrode, or an alloy electrode. A material of the doped metal oxide electrode is selected from one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO), and cadmium-doped zinc oxide. The composite electrode is an electrode formed by laminating two or more layers of conductive materials, such as AZO/Ag/AZO, AZO/AI/AZO, ITO/Ag/ITO, ITO/AV/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, Ca/Al, LiF/Ca, LiF/Al, BaF₂/Al, CsF/Al, CaCO₃/Al, and BaF₂/Ca/Al, etc., where “/” denotes a laminated structure, for example, AZO/Ag/AZO denotes a composite electrode including an AZO layer, an Ag layer and an AZO layer which are sequentially laminated. A material of the metallic electrode is selected from silver (Ag), magnesium (Mg), aluminum (Al), gold (Au), gallium (Ga), nickel (Ni), platinum (Pt), iridium (Ir), copper (Cu), molybdenum (Mo), calcium (Ca), and barium (Ba). The alloy electrode is selected from an Au: Mg alloy electrode or an Ag: Mg alloy electrode.

In some embodiments, one of the first electrode 20 and the second electrode 70 as an anode may be an electrode with a relatively high work function, which may be selected from one or more of a doped metal oxide electrode with a relatively high work function, a metallic elemental electrode with a relatively high work function, and a carbon nanotube electrode. A material of the simple metal electrode with relatively high function can be Ni, Pt, Au, Ag or Ir.

In some embodiments, one of the first electrode 20 and the second electrode 70 as a cathode may be an electrode with a relatively low work function, which may be selected from one or more of a simple metal electrode with a relatively low work function, a composite electrode with a relatively low work function and an alloy electrode with a relatively low work function. A material of the metallic electrode with relatively low work function can be Ca, Ba, Al, and Mg, etc. A structure of the composite electrode with relatively low work function can be Ca/Al, LiF/Ca, LiF/Al, BaF₂/Al, CsF/Al, CaCO₃/Al, and BaF₂/Ca/Al, etc. The alloy electrode with relatively low work function can be Au: Mg or Ag: Mg, etc.

Illustratively, a thickness of the first electrode 20 ranges from 10 nm-120 nm, such as 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, and 85 nm, etc.

Illustratively, a thickness of the second electrode 70 ranges from 10 nm-120 nm, such as 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, and 85 nm, etc.

Illustratively, a thickness of the hole injection layer 30 ranges from 10 nm-50 nm, such as 10 nm, 12 nm, 15 nm, 18 nm, 20 nm, 22 nm, 25 nm, 28 nm, 30 nm, 32 nm, 35 nm, 38 nm, 40 nm, 45 nm, 48 nm, and 50 nm, etc.

Illustratively, a thickness of the hole transport layer 40 ranges from 10 nm-50 nm, such as 10 nm, 12 nm, 15 nm, 18 nm, 20 nm, 22 nm, 25 nm, 28 nm, 30 nm, 32 nm, 35 nm, 38 nm, 40 nm, 45 nm, 48 nm, and 50 nm, etc.

Illustratively, a thickness of the electron transport layer 60 ranges from 10 nm-50 nm, such as 10 nm, 12 nm, 15 nm, 18 nm, 20 nm, 22 nm, 25 nm, 28 nm, 30 nm, 32 nm, 35 nm, 38 nm, 40 nm, 45 nm, 48 nm, and 50 nm, etc.

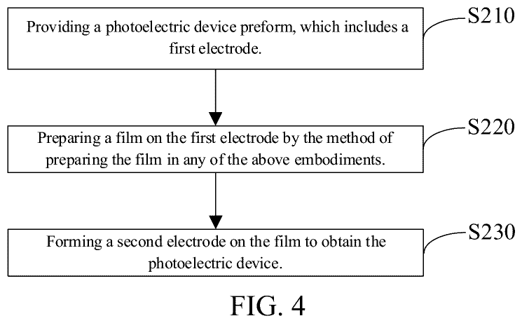

Referring to FIG. 4, in conjunction with FIG. 2 and FIG. 3, the present disclosure a preparation method of a photoelectric device, including:

S210, providing a photoelectric device preform, which includes a first electrode 20, S220, preparing a film 50 on the first electrode 20 by the method of preparing the film in any of the above embodiments,

S230, forming a second electrode 70 on the film 50 to obtain the photoelectric device 100.

Referring to FIG. 2 and FIG. 3, the photoelectric device preform may further include a substrate 10, and the first electrode 20 is disposed on one side of the substrate 10.

Referring to FIG. 2, when the first electrode 20 is an anode and the second electrode 70 is a cathode, the method for preparing the film 50 on the first electrode 20 in any of the above embodiments includes: forming a hole injection layer 30 on the first electrode 20, forming a hole transport layer 40 on the side of the hole injection layer 30 away from the first electrode 20, and preparing the film 50 on the hole transport layer 40 in any of the above embodiments.

The forming of the second electrode 70 on the thin film 50 includes forming the electron transport layer 60 on the film 50, and forming the second electrode 70 on the side of the electron transport layer 60 facing away from the film 50.

Referring to FIG. 3, when the first electrode 20 is a cathode and the second electrode 70 is an anode, the method for preparing the film 50 on the first electrode 20 in any of the above embodiments includes forming an electron transport layer 60 on the first electrode 20, and forming the film 50 on the side of the electron transport layer 60 facing away from the first electrode 20 in any of the above embodiments.

Forming the second electrode 70 on the film 50 includes forming the hole transport layer 40 on the film 50, forming the hole injection layer 30 on the side of the hole transport layer 40 away from the film 50, and forming the second electrode 70 on the side of the hole injection layer 30 away from the hole transport layer 40.

The present also disclosure a display device, including the photoelectric device in any of the above embodiments, or the photoelectric device manufactured by the method for manufacturing the photoelectric device in any of the above embodiments.

Illustratively, the display device can be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device can be a smart bracelet, smart glasses, and a smart watch.

In the following, the film of the embodiment of the present, its preparation method and photoelectric device are introduced in detail in the form of specific examples.

### Film Example 1

This example provides a film, and its preparation method includes: adding cellulose nanofiber (manufactured by Nanografi,) into a quantum dot solution (a solvent is octane, and a mass ratio of the cellulose nanofiber to the quantum dot is 0.03:1) to prepare a quantum dot nanocellulose composite solution, in which a concentration of the quantum dot (CdZnSe) is 30 mg/ml and a concentration of the cellulose nanofiber is 0.9 mg/ml; and spin-coating the quantum dot nanocellulose composite solution on a hole transport layer at the speed of 2000 rpm for 30 seconds to obtain the film. A thickness of the film is 30 nm.

### Film Example 2

This example provides a film, and its preparation method is different from that of the film example 1 in that a mass ratio of the cellulose nanofiber to the quantum dot is different when preparing the quantum dot nanocellulose composite solution, so that the concentration of the cellulose nanofiber in the quantum dot nanocellulose composite solution is different. In this example 2, a mass ratio of the cellulose nanofiber to the quantum dot in the quantum dot nanocellulose composite solution is 0.01:1. A concentration of the cellulose nanofiber in the quantum dot nanocellulose composite solution is 0.3 mg/ml, and a concentration of the quantum dot (CdZnSe) is 30 mg/ml.

### Film Example 3

This example provides a film, and its preparation method is different from that of the film example 1 in that a mass ratio of the cellulose nanofiber to the quantum dot is different when preparing the quantum dot nanocellulose composite solution, so that the concentration of the cellulose nanofiber in the quantum dot nanocellulose composite solution is different. In this example 3, a mass ratio of the cellulose nanofiber to the quantum dot in the quantum dot nanocellulose composite solution is 0.05:1. A concentration of the cellulose nanofiber in the quantum dot nanocellulose composite solution is 0.5 mg/ml, and a concentration of the quantum dot (CdZnSe) is 30 mg/ml.

### Film Example 4

This example provides a film, and its preparation method is different from that of the film example 1, in that when preparing the quantum dot nanocellulose composite solution, a type of the nano cellulose used in example 1 is different, while the nano cellulose used in example 4 is cellulose nanocrystal (manufactured by Nanografi).

### Film Example 5

This example provides a film, and its preparation method is different from that of the film example 1, in that when preparing the quantum dot nanocellulose composite solution, a type of the nano cellulose used in example 1 is different, while the nano cellulose used in example 5 is bacterial nanocellulose (manufactured by Cellulose Lab).

### Film Example 6

This example provides a film, and its preparation method is different from that of the film example 1, in that a crosslinking agent, 3-aminopropyl triethoxysilane (Sigma Aldrich, APTES, cas: 919-30-2), is also added to the quantum dot nanocellulose composite solution, wherein a concentration of 3-aminopropyl triethoxysilane is 0.02 mg/ml. At this moment, a mass ratio between 3-aminopropyl triethoxysilane and the cellulose nanofibers is 2.22:100. Furthermore, after the spin-coating the quantum dot nanocellulose composite solution on the hole transport layer, a film layer to be crosslinked is obtained, and the film layer to be crosslinked is placed in a constant temperature and humidity box with a temperature of 80° C. and a humidity of 80% for 10 minutes, so that the 3-aminopropyl triethoxysilane in the film layer to be crosslinked reacts with the nanocellulose to obtain the film.

### Film Example 7

This example provides a film, and its preparation method is different from that of the film example 1, in that a crosslinking agent, maleic anhydride (Sigma Aldrich, cas: 108-31-6), is also added to the quantum dot nanocellulose composite solution, wherein a concentration of maleic anhydride is 0.08 mg/ml. At this moment, a mass ratio between maleic anhydride and the cellulose nanofibers is 8.89:100. Furthermore, after the spin-coating the quantum dot nanocellulose composite solution on the hole transport layer, a film layer to be crosslinked is obtained, and heat-treating the film layer to be crosslinked on a hot stage at 100° C. for 30 minutes, so that the maleic anhydride in the film layer to be crosslinked reacts with the nanocellulose to obtain the film.

### Film Example 8

This example provides a film, and its preparation method is different from that of the film example 1, in that a mass ratio of the cellulose nanofiber to the quantum dot is different in the quantum dot nanocellulose composite solution, so that a concentration of the cellulose nanofiber in the quantum dot nanocellulose composite solution is different. In this example 8, a mass ratio of the cellulose nanofiber to the quantum dot in the quantum dot nanocellulose composite solution is 0.001:1, and a concentration of the cellulose nanofiber in the quantum dot nanocellulose composite solution is 0.03 mg/ml.

### Film Example 9

This example provides a film, and its preparation method is different from that of the film example 1, in that a mass ratio of the cellulose nanofiber to the quantum dot is different in the quantum dot nanocellulose composite solution, so that a concentration of the cellulose nanofiber in the quantum dot nanocellulose composite solution is different. In this example 9, a mass ratio of the cellulose nanofiber to the quantum dot in the quantum dot nanocellulose composite solution is 0.1:1, and a concentration of the cellulose nanofiber in the quantum dot nanocellulose composite solution is 3 mg/ml.

### Photoelectric Device Example 10

This example provides a photoelectric device, and its preparation method includes steps S1-S5.

In step S1, PEDOT: PSS on a PET/ITO substrate is spin-coated at a rotating speed of 5000 rpm for 30 seconds, and then heating at 150° C. for 15 minutes to obtain a hole injection layer with a thickness of 25 nm.

In step S2, TFB is spin-coated on the hole injection layer with rotating at 3000 rpm for 30 seconds, then UV-treating for 10 minutes, and then heating at 200° C. for 10 minutes to obtain a hole transport layer with a thickness of 30 nm.

In step S3, a film is formed on the hole transport layer by the method of the film example 1.

In step S4, a zinc oxide (ZnO) solution (a concentration of ZnO is 30 mg/ml) is spin-coated on the film with rotating at 3000 rpm for 30 seconds, and then heating at 80° C. for 30 minutes to obtain an electron transport layer with a thickness of 30 nm.

In step S5: Ag is plated under a condition that a vacuum degree is not higher than 3×10⁴ Pa, a speed is 1 Å/s, and a time is 1000 seconds, to obtain a cathode with a thickness of 100 nm, and a top-emitting positive quantum dot photoelectric device.

### Photoelectric Device Example 11

This example provides a photoelectric device, and its preparation method is different from that of the photoelectric device example 10 in that in S3, a film is formed on the hole transport layer by the method of film example 2.

### Photoelectric Device Example 12

This example provides a photoelectric device, and its preparation method is different from that of the photoelectric device example 10 in that in S3, a film is formed on the hole transport layer by the method of film example 3.

### Photoelectric Device Example 13

This example provides a photoelectric device, and its preparation method is different from that of the photoelectric device example 10 in that in S3, a film is formed on the hole transport layer by the method of film example 4.

### Photoelectric Device Example 14

This example provides a photoelectric device, and its preparation method is different from that of the photoelectric device example 10 in that in S3, a film is formed on the hole transport layer by the method of film example 5.

### Photoelectric Device Example 15

This example provides a photoelectric device, and its preparation method is different from that of the photoelectric device example 10 in that in S3, a film is formed on the hole transport layer by the method of film example 6.

### Photoelectric Device Example 16

This example provides a photoelectric device, and its preparation method is different from that of the photoelectric device example 10 in that in S3, a film is formed on the hole transport layer by the method of film example 7.

### Photoelectric Device Example 17

This example provides a photoelectric device, and its preparation method is different from that of the photoelectric device example 10 in that in S3, a film is formed on the hole transport layer by the method of film example 8.

### Photoelectric Device Example 18

This example provides a photoelectric device, and its preparation method is different from that of the photoelectric device example 10 in that in S3, a film is formed on the hole transport layer by the method of film example 9.

### Photoelectric Device Comparative Example 1

This comparative example provides a photoelectric device, and its preparation method is different from that of the photoelectric device example 10 in that in S3 includes: spin-coating a quantum dot solution on the hole transport layer at a rotation speed of 2000 rpm for 30 seconds to obtain a film with a thickness of 30 nm, wherein the quantum dot solution is composed of quantum dot CdZnSe and a solvent (octane), and a concentration of the quantum dot CdZnSe is 30 mg/ml.

### Performance Test:

The performance of photoelectric devices prepared in the photoelectric device example 10-18 and the photoelectric device comparative example 1 was tested, and an initial performance (maximum brightness Lₘₐₓ, lifetime T95) and life loss of photoelectric devices after different bending times at normal temperature (25° C.) and high temperature (80° C.) were tested.

The maximum brightness Lₘₐₓ is calculated based on the parameters such as voltage, current, brightness and luminescence spectrum which are measured by operating Faust FPD optical characteristic measuring equipment, and using LabView to control the efficiency test system built by QE PRO spectrometer, Keithley 2400 and Keithley 6485.

A test method of the life T95 is: in N₂ gas, driven by constant current, the time taken for the brightness of the device to decay to a certain proportion of the maximum brightness is measured, and the time for the brightness to decay to 95% of the maximum brightness is defined as T95, which is the measured life, wherein the constant current is 2 mA.

A calculation formula of the life loss of photoelectric devices is: (1−device life after bending/initial device life)*100.

The test results are shown in Table 1, Table 2 and Table 3, in which Table 1 shows the life decay of photoelectric devices after different bending times at normal temperature (25° C.), Table 2 shows the life decay of photoelectric devices after different bending times at high temperature (80° C.), and Table 3 shows the initial performance (maximum brightness Lₘₐₓ, and life T95) of photoelectric devices.

TABLE 1
The life decay of photoelectric devices after different
bending times (25° C.)

| | Percentage of | Percentage of | Percentage of |
|---|---|---|---|
| | life loss after | life loss after | life loss after |
| | bending for | bending for | bending for |
| | 20,000 times | 50,000 times | 150,000 times |
| | (%) | (%) | (%) |
| Example 10 | 4.1 | 7.6 | 11.1 |
| Example 11 | 4.3 | 7.7 | 11.4 |
| Example 12 | 4.2 | 7.5 | 10.9 |
| Example 13 | 3.8 | 6.6 | 8.6 |
| Example 14 | 4.8 | 8.2 | 12.1 |
| Example 15 | 3.9 | 6.7 | 8.4 |
| Example 16 | 3.8 | 6.5 | 8.5 |
| Example 17 | 16.1 | 30.5 | 61.2 |
| Example 18 | 1.9 | 2.9 | 3.7 |
| Comparative | 20.3 | 41.9 | 74.7 |
| Example 1 | | | |

TABLE 2
The life decay of photoelectric devices after different
bending times (80° C.)

| | Percentage of | Percentage of | Percentage of |
|---|---|---|---|
| | life loss after | life loss after | life loss after |
| | bending for | bending for | bending for |
| | 20,000 times | 50,000 times | 150,000 times |
| | (%) | (%) | (%) |
| Example 10 | 10.1 | 19.2 | 27.5 |
| Example 11 | 11.0 | 20.6 | 29.1 |
| Example 12 | 10.3 | 18.8 | 26.8 |
| Example 13 | 9.8 | 15.6 | 20.6 |
| Example 14 | 10.8 | 20.2 | 28.1 |
| Example 15 | 5.1 | 8.9 | 12.2 |
| Example 16 | 4.6 | 8.3 | 12.4 |
| Example 17 | 28.2 | 42.8 | 77.2 |
| Example 18 | 9.9 | 15.5 | 19.7 |
| Comparative | 30.2 | 50.9 | 81.2 |
| Example 1 | | | |

TABLE 3
Initial performance of photoelectric devices

| | Lₘₐₓ (nit) | Lifetime T95 (h) |
|---|---|---|
| Example 10 | 5112 | 5.2 |
| Example 11 | 5241 | 4.9 |
| Example 12 | 5107 | 5.4 |
| Example 13 | 5015 | 5.2 |
| Example 14 | 5156 | 4.1 |
| Example 15 | 5023 | 5.0 |
| Example 16 | 5011 | 5.3 |
| Example 17 | 5225 | 4.3 |
| Example 18 | 1031 | 2.7 |
| Comparative | 5231 | 4.7 |
| Example 1 | | |

As can be seen from Table 1, under the normal temperature (25° C.), the percentage of life loss of the photoelectric devices of examples 10-18 after bending for 20,000 times, 50,000 times and 150,000 times is less than that of the photoelectric devices of comparative example 1 after bending for 20,000 times, 50,000 times and 150,000 times. As can be seen from Table 2, at high temperature (80° C.), the percentage of life loss of the photoelectric devices of examples 10-18 after bending for 20,000 times, 50,000 times and 150,000 times is less than that of the photoelectric devices of comparative example 1 after bending for 20,000 times, 50,000 times and 150,000 times. Compared with comparative example 1, the photoelectric devices of examples 10-18 have better stability and longer service life under normal temperature (25° C.) and high temperature (80° C.). It is known that all the films in the photoelectric devices of examples 10-18 contain nanocellulose, while the films in the photoelectric devices of comparative example 1 do not contain nanocellulose, which shows that the films containing nanocellulose still have good stability and bending resistance after being bent for many times, so that the photoelectric devices containing the films have more stable device performance and longer service life.

As can be seen from Table 1, at normal temperature (25° C.), the percentage of life loss of photoelectric devices in examples 10-16 and example 18 after bending for 20,000 times, 50,000 times and 150,000 times is less than that of photoelectric devices in example 17 after bending for 20,000 times, 50,000 times and 150,000 times. As can be seen from Table 2, at high temperature (80° C.), the percentage of life loss of photovoltaic devices in examples 10-16 and example 18 after bending for 20,000 times, 50,000 times and 150,000 times are all less than that of photoelectric devices in example 17 after bending for 20,000 times, 50,000 times and 150,000 times. Compared with example 17, the photoelectric devices of examples 10-16 and example 18 have better stability and longer service life under normal temperature (25° C.) and high temperature (80° C.). It is known that the mass ratio of nanocellulose to quantum dot in the films of the photoelectric devices of examples 10-16 and example 18 is between 0.01:1 and 0.05:1, while the mass ratio of nanocellulose to quantum dot in the film of the photoelectric devices of example 17 is 0.001:1, which shows that when the content of nanocellulose in the films is higher than 0.01:1, when the films are bent, nanocellulose can well maintain the stability of the position of quantum dot particles, so as to slow down or eliminate the crack or fracture of the thin film during bending, and further improve the stability and service life of photoelectric devices.

As can be seen from Table 2, at high temperature (80° C.), the percentage of life loss of the photoelectric device in example 10 after bending for 20,000 times, 50,000 times and 150,000 times is greater than that of the photoelectric devices in example 15 and example 16 after bending for 20,000 times, 50,000 times and 150,000 times. Compared with example 10, the photoelectric devices of example 15 and example 16 have better stability and longer service life. It is known that the difference between example 15, example 16 and example 10 is that the film also contains crosslinking agent, which shows that when the film contains crosslinking agent, the film has better bending resistance, thus making the photoelectric device have better stability and longer service life.

As can be seen from Table 1, Table 2 and Table 3, it can be seen that although the life loss of the photoelectric device of example 18 after bending is low at normal temperature (25° C.) and high temperature (80° C.), its initial performance is poor, and the Lₘₐₓ and lifetime T95 are low, which is because the content of nanocellulose (cellulose nanofiber) in the film of the photoelectric device of example 18 is high. The mass ratio of nanocellulose to quantum dot is 0.1:1, far exceeding the mass ratio of nanocellulose to quantum dot in examples 10-16 (0.01:1 to 0.05:1), which shows that when the mass ratio of nanocellulose to quantum dot in the film does not exceed 0.05:1, not only the bending resistance of the film can be improved, but also the photoelectric device can have better luminous performance and longer service life.

A film, a preparation method thereof and a photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A film, comprising:
a nanocellulose; and
an inorganic nanoparticle;
wherein the nanocellulose has a porous skeleton, and the inorganic nanoparticle is located in pores of the porous skeleton.

2. The film according to claim 1, wherein a mass ratio of the nanocellulose to the inorganic nanoparticle is (0.01-0.05): 1;
the nanocellulose is selected from one or more of cellulose nanocrystal, cellulose nanofiber, and bacterial nanocellulose.

3. The film according to claim 1, further comprising a crosslinking agent selected from one or more of silane and acid anhydride.

4. The film according to claim 3, wherein the silane is connected to the nanocellulose; the acid anhydride is connected to the nanocellulose; a mass ratio of the crosslinking agent to the nanocellulose is (0.5-10): 100.

5. The film according to claim 4, wherein the silane is connected to the nanocellulose through at least one siloxane bond, and the acid anhydride is connected to the nanocellulose through at least one ester bond.

6. The film according to claim 3, wherein the silane is selected from one or more of 3-aminopropyl triethoxysilane, methyltrioxysilane, styrene dimethoxysilane, and aminopropyl trimethoxysilane; the acid anhydride is selected from one or more of maleic anhydride, succinic anhydride, and phthalic anhydride.

7. The film according to claim 3, wherein the crosslinking agent is the silane, a mass ratio of the crosslinking agent to the nanocellulose is (0.5-5): 100; or
the crosslinking agent is the acid anhydride, a mass ratio of the crosslinking agent to the nanocellulose is (1-10): 100; or
the crosslinking agent comprises a mixture of the silane and the acid anhydride, and a mass ratio of the silane to the acid anhydride is (1-100):(1-100).

8. The film according to claim 1, wherein a material of the inorganic nanoparticle is selected from quantum dot luminescent material;
the quantum dot luminescent material is selected from one or more of single structure quantum dot and core-shell structure quantum dot; a material of the single structure quantum dot, a core material of the core-shell quantum dot and a shell material of the core-shell quantum dot is independently selected from one or more of II-VI compound, IV-VI compound, III-V compound and I-III-VI compound; the core-shell structure quantum dot comprises one or more shell layers; the II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GalnNP, GalnNAs, GalnNSb, GalnPAs, GaInPSb, InAINP, InAINAs, InAINSb, InAlPAs, and InAlPSb; the I-III-VI compound is selected from one or more of CuInS₂, CuInSe₂, and AgInS₂.

9. A preparation method of a film, comprising:
providing an inorganic nanomaterial solution, wherein the inorganic nanomaterial solution comprises a nanocellulose, an inorganic nanoparticle and a solvent; and
depositing the inorganic nanomaterial solution to obtain a film, wherein the film comprises the nanocellulose and the inorganic nanoparticle, the nanocellulose forms a porous skeleton, and the inorganic nanoparticle is located in pores of the porous skeleton.

10. The preparation method according to claim 9, wherein in the inorganic nanomaterial solution, a concentration of the inorganic nanoparticle ranges between 10 mg/ml-50 mg/ml, and a concentration of the nanocellulose ranges between 0.1 mg/ml-2.5 mg/ml;
a mass ratio of the nanocellulose to the inorganic nanoparticle is (0.01-0.05): 1.

11. The preparation method according to claim 9, wherein the inorganic nanomaterial solution further comprises a crosslinking agent selected from one or more of silane and acid anhydride.

12. The preparation method according to claim 11, wherein a mass ratio of the crosslinking agent to the nanocellulose is (0.5-10): 100, and a concentration of the crosslinking agent in the inorganic nanomaterial solution ranges between 0.0005 mg/ml-0.25 mg/ml.

13. The preparation method according to claim 11, wherein the crosslinking agent is the silane, a mass ratio of the crosslinking agent to the nanocellulose is (0.5-5): 100, and a concentration of the crosslinking agent in the inorganic nanomaterial solution ranges between 0.0005 mg/ml-0.125 mg/ml; or
the crosslinking agent is the acid anhydride, a mass ratio of the crosslinking agent to the nanocellulose is (1-10):100, and a concentration of the crosslinking agent in the inorganic nanomaterial solution ranges between 0.001 mg/ml-0.25 mg/ml.

14. The preparation method according to claim 11, wherein the depositing the inorganic nanomaterial solution to obtain the film comprises:
depositing the inorganic nanomaterial solution to obtain a film layer to be crosslinked; and
heat-treating the film layer to be crosslinked in an environment with a temperature of 80° C.-100° C. and a humidity of 80%-100% for 10 min-60 min, so that the crosslinking agent and the nanocellulose have a crosslinking reaction to obtain the film.

15. The preparation method according to claim 9, wherein the nanocellulose is selected from one or more of cellulose nanocrystal, cellulose nanofiber, and bacterial nanocellulose;
a material of the inorganic nanoparticle is selected from quantum dot luminescent material; the quantum dot luminescent material is selected from one or more of single structure quantum dot and core-shell structure quantum dot; specifically, a material of the single structure quantum dot, a core material of the core-shell quantum dot and a shell material of the core-shell quantum dot is independently selected from one or more of II-VI compound, IV-VI compound, III-V compound and I-III-VI compound; the core-shell structure quantum dot comprises one or more shell layers; the II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GaInNP, GalnNAs, GaInNSb, GalnPAs, GaInPSb, InAINP, InAINAs, InAINSb, InAlPAs, and InAlPSb; the I-III-VI compound is selected from one or more of CuInS₂, CuInSe₂, and AgInS₂.

16. A photoelectric device, comprising:
a first electrode;
a second electrode; and
a film, between the first electrode and the second electrode, comprising:
a nanocellulose; and
an inorganic nanoparticle;
wherein the nanocellulose has a porous skeleton, and the inorganic nanoparticle is located in pores of the porous skeleton.

17. The photoelectric device according to claim 16, further comprising:
a hole injection layer, located on the first electrode;
a hole transport layer, located between the film and the first electrode; and
an electron transport layer located between the film and the second electrode, wherein the first electrode is an anode and the second electrode is a cathode.

18. The photoelectric device according to claim 16, further comprising:
an electron transport layer, located between the film and the first electrode;
a hole transport layer, located between the film and the second electrode; and
a hole injection layer located between the hole transport layer and the second electrode, wherein the first electrode is a cathode and the second electrode is an anode.

19. The photoelectric device according to claim 17, wherein a material of the hole transport layer is selected from one or more of 4,4′-N,N′-dicarbcarbazolyl-biphenyl, poly [bis(4-phenyl) (2,4,6-trimethylphenyl)amine], N,N′-diphenyl-N,N′-bis(1-naphthyl)-1,1′-biphenyl-4,4″-diamine, N,N′-diphenyl-N,N′-bis(1-naphthyl)-4,4′-diamine, poly(N,N′ bis(4-butylphenyl)-N,N′-bis(phenyl)benzidine), N,N′-bis(4-(N,N′-diphenyl-amino)phenyl)-N,N′-diphenyl benzidine, 4,4′,4′-tris(N-carbazolyl)-triphenylamine, 4,4′,4′-tris(N-3-methylphenyl-N-phenylamino)triphenylamine, poly [(9,9′-dioctyl fluorene-2,7-diyl)-co-(4,4′-(N-(4-sec-butylphenyl)diphenylamine))], poly(N-vinylcarbazole) and its derivatives, N,N′-bis(1-naphthyl)-N,N′-diphenyl-1,1′-biphenyl-4-4′-diamine, poly(phenylene vinylene), poly [2-methoxy-5-(2-ethylhexyloxy)-1,4-phenylene vinylene], poly [2-methoxy-5-(3′,7′-dimethyloctyloxy)-1,4-phenylene vinylene], 2,2′,7,7′-tetrakis [N,N-bis(4-methoxyphenyl)amino]-9,9′-spiro-fluorene, 4,4′-cyclohexyl bis [N,N-bis(4-methylphenyl) aniline], 1,3-bis(carbazole-9-yl)benzene, polyaniline, polypyrrole, poly(p) phenylene vinylene, aromatic tertiary amine, polynuclear aromatic tertiary amine, 4,4′-bis(p-carbazolyl)-1,1′-biphenyl compound, N,N,N′,N′-tetraarylbenzidine, poly(3,4-ethylenedioxythiophene)-polystyrene sulfonic acid and its derivatives, polymethacrylate and its derivatives, poly(9,9-octylfluorene) and its derivatives, polyspirofluorene and its derivatives, and polythiophene and its derivatives;
a material of the hole injection layer is selected from one or more of poly(3,4-ethylenedioxythiophene)-polystyrene sulfonic acid, copper phthalocyanine, 2,3,6,7,10,11-hexacyano-1,4,5,8,9,12-hexazaphenanthrene, polyoxyethyl cephene, PEDOT: PSS doped with MoO₃, 4,4′,4′-tris(N-3-methylphenyl-N-phenylamino)triphenylamine, tetracyanoquinone dimethane, transition metal oxide, and transition metal chalcogenide; and the transition metal oxide is selected from one or more of MoOₓ, VOₓ, WOₓ, CrOₓ and CuO, the metal chalcogenide is selected from one or more of MoS₂, MoSe₂, WS₂, WSe₂, and CuS;
a material of the electron transport layer is selected from one or more of metal oxide, doped metal oxide, II-VI semiconductor material, III-V semiconductor material and I-III-VI semiconductor material, and the metal oxide is selected from one or more of ZnO, BaO, TiO₂, and SnO₂; a metal oxide in the doped metal oxide is selected from one or more of ZnO, TiO₂, and SnO₂, a doping element is selected from one or more of Al, Mg, Li, In and Ga; and the II-VI semiconductor family material is selected from one or more of ZnS, ZnSe and CdS; the III-V semiconductor material is selected from one or more of InP and GaP; the I-III-VI semiconductor material is selected from one or more of CuInS and CuGaS;
the first electrode and the second electrode each is independently selected from a doped metal oxide electrode, a composite electrode, a graphene electrode, a carbon nanotube electrode, a simple metal electrode, or an alloy electrode; and a material of the doped metal oxide electrode is selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, aluminum-doped magnesium oxide, and cadmium-doped zinc oxide; and the composite electrode is selected from AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, Ca/Al, LiF/Ca, LiF/Al, BaF₂/Al, CsF/Al, CaCO₃/Al, and BaF₂/Ca/Al; and a material of the metallic electrode is selected from Ag, Mg, Al, Au, Ga, Ni, Pt, Ir, Cu, Mo, Ca, and Ba.
